(19) United States
(12) Patent Application Publication
(10) Pub. No.: US 2010/0122774 A1
(43) Pub. Date: May 20, 2010

(54) SUBSTRATE MOUNTING TABLE AND SUBSTRATE PROCESSING APPARATUS HAVING SAME

(75) Inventors: Toshiyuki MAKABE, Nirasaki City (JP); Taketoshi Okajo, Nirasaki City (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/613,096

(22) Filed: Nov. 5, 2009

(30) Foreign Application Priority Data
Nov. 20, 2008 (JP) 2008-297280

(51) Int. Cl. H01L 21/306

(52) U.S. Cl. 156/345.52

(57) ABSTRACT

A substrate mounting table includes a mounting table main body, a mounting unit provided at an upper portion of the mounting table main body, a heat source transferring a (cold) heat to the upper portion of the mounting table main body, and a heat transfer control part. The heat transfer control part includes a cavity portion provided in the mounting table main body to correspond to the mounted substrate, and a solid member filled in the cavity portion and having pores communicating with one another. The heat transfer control part controls a heat transfer level from the heat source by supplying or exhausting a heat transfer gas to or from the cavity portion. A controller controls the supplying and the exhausting of the heat transfer gas to and from the cavity portion by a heat transfer gas supply unit and a heat transfer gas exhaust unit, respectively.

### CROSS-REFERENCE TO RELATED APPLICATIONS

This application claims priority to Japanese Patent Application No. 2008-297280 filed on Nov. 20, 2008, the entire contents of which are incorporated herein by reference.

### FIELD OF THE INVENTION

The present invention relates to a substrate mounting table on which a substrate such as a semiconductor wafer or the like is mounted; and a substrate processing apparatus for performing a processing, e.g., a dry etching on a substrate mounted on the substrate mounting table.

### BACKGROUND OF THE INVENTION

In the manufacturing process of a semiconductor device, a target substrate, e.g., a semiconductor wafer, is subjected to a plasma processing such as a dry etching, a sputtering, a chemical vapor deposit (CVD), or the like. For example, in a plasma etching process, a mounting table for mounting a wafer thereon is provided inside a chamber and the wafer is electrostatically attracted to and held by an electrostatic chuck which constitutes an upper part of the mounting table. Then, a plasma is generated by using a processing gas to subject the wafer to a plasma etching process.

When such a plasma processing is performed, it is required to control the temperature of the wafer, to a desirable level. For that reason, a coolant path is provided inside the mounting table; and a heat transfer gas such as He gas is supplied to a gap between a backside of the wafer and the mounting table on which the wafer is mounted. The pressure of the He gas is changed to adjust the temperature of the wafer, to thereby control a processing rate such as an etching rate or the like.

However, as recent semiconductor devices have gotten smaller, the temperature of a wafer needs to be more precisely adjusted to perform a plasma processing such as a plasma etching or the like with higher precision. Moreover, in the case of carrying out a waferless dry cleaning in a chamber of the plasma processing apparatus, it is required to increase the temperature of the mounting table rather than cooling it by the coolant.

A technique has been developed to meet such a requirement (see, e.g., Japanese Patent Laid-open publication No. 2001-110885). According to the technique, a heat transfer gas chamber capable of performing gas sealing and gas exhausting is provided between a coolant path and a support member constituted by an electrostatic chuck of a mounting table (adsorption device) and the heat transfer is controlled to adjust the temperature of a wafer.

However, according to the technique, a cavity as the heat transfer gas chamber is provided and, thus, it is difficult to machine the mounting table to be flat. Moreover, the mounting table is warped by the pressure difference when the cavity is kept vacuum. These may cause insufficient contact of the mounted wafer with the mounting table to deteriorate the temperature controllability of the wafer.

Further, even though a gas is filled in the cavity, the cavity has a thermal conductivity inferior to that of a solid material. Accordingly, the cavity can not be sufficiently cooled in a recent high powered process. As a result, the temperature of the cavity only becomes high as a singularity. The cavity is also easily affected by the plasma serving as a heat source.

These may cause the in-plane temperature of a wafer to be nonuniform, which results in nonuniform etching rate. Therefore, the in-plane temperature uniformity of the wafer is required. However, in the aforementioned technique, it is difficult to control the in-plane temperature of the wafer to be uniform. Further, due to the processing gas, deposits may be easily locally attached to an exposed area of the mounting table cooled by the coolant. In the technique, it is also difficult to prevent such local attachment of the deposits.

### SUMMARY OF THE INVENTION

In view of the above, the present invention provides a substrate mounting table capable of being sufficiently brought into contact with a substrate to adjust the temperature of the substrate to a preset level with high precision and a substrate processing apparatus having same.

Further, the present invention provides a substrate mounting table capable of improving an in-plane temperature uniformity of a substrate and preventing deposits from being attached to a local portion of the mounting table and a substrate processing apparatus having same.

In accordance with a first aspect of the present invention, there is provided a substrate mounting table for mounting a substrate thereon in a substrate processing apparatus. The substrate mounting table includes: a mounting table main body; a mounting unit provided at an upper portion of the mounting table main body and having a mounting surface on which the substrate is mounted; a heat source configured to transfer a cold heat or a heat to the upper portion of the mounting table main body; a heat transfer control part including a cavity portion provided in a heat transfer path of the mounting table main body to correspond to the mounted substrate and a solid member filled in the cavity portion and having pores that communicate with one another, the heat transfer control part controlling a heat transfer level from the heat source by supplying or exhausting a heat transfer gas to or from the cavity portion; a heat transfer gas supply unit for supplying the heat transfer gas to the cavity portion; a heat transfer gas exhaust unit for exhausting the heat transfer gas from the cavity portion; and a controller for controlling the supplying and the exhausting of the heat transfer gas to and from the cavity portion by the heat transfer gas supply unit and the heat transfer gas exhaust unit, respectively.

In accordance with a second aspect of the present invention, there is provided a substrate mounting table for mounting a substrate thereon in a substrate processing apparatus. The substrate mounting table includes: a mounting table main body; a mounting unit provided at an upper portion of the mounting table main body and having a mounting surface on which the substrate is mounted; a plurality of different-temperature heat sources configured to transfer cold heats or heats to the upper portion of the mounting table main body; a heat transfer control part including a cavity portion provided between the heat sources of the mounting table main body and a solid member filled in the cavity portion and having pores that communicate with one another, the heat transfer control part controlling a heat transfer level between the heat sources by supplying or exhausting a heat transfer gas to or from the cavity portion; a heat transfer gas supply unit for supplying the heat transfer gas to the cavity portion; a heat transfer gas exhaust unit for exhausting the heat transfer gas from the cavity portion; and a controller for controlling the supplying and the exhausting of the heat transfer gas to and from the cavity portion by the heat transfer gas supply unit and the heat transfer gas exhaust unit, respectively.

In accordance with a third aspect of the present invention, there is provided a substrate processing apparatus including a processing chamber configured to accommodate a substrate therein, the inside of the processing chamber being depressurized; a substrate mounting table provided in the processing chamber, the substrate being mounted on the substrate mounting table; and a processing unit for performing a predetermined processing on the substrate in the processing chamber.

### BRIEF DESCRIPTION OF THE DRAWINGS

The objects and features of the present invention will become apparent from the following description of embodiments, given in conjunction with the accompanying drawings, in which:

FIG. 1 is a cross sectional view showing a plasma processing apparatus including a wafer mounting table in accordance with a first embodiment of the present invention;

FIG. 2 is a cross sectional view showing a wafer mounting table in accordance with the first embodiment of the present invention;

FIG. 3 is an enlarged cross sectional view showing a status of a heat transfer control part when a minute space is employed as a cavity portion of the heat transfer control part in the wafer mounting table shown in FIG. 1;

FIG. 4 is a graph showing a relationship between a thermal conductivity and a pressure of gas depending on various heights when a minute space is employed as a cavity portion of a heat transfer control part;

FIG. 5 is a block diagram showing a control unit installed in the plasma processing apparatus shown in FIG. 1;

FIG. 6 is a cross sectional view showing a wafer mounting table in accordance with a second embodiment of the present invention;

FIG. 7 is a cross sectional view showing a wafer mounting table in accordance with a third embodiment of the present invention;

FIG. 8 is a cross sectional view showing another example of a heat transfer control part in the wafer mounting table in accordance with the third embodiment of the present invention; and

FIG. 9 is a cross sectional view showing a wafer mounting table in accordance with a fourth embodiment of the present invention.

### DETAILED DESCRIPTION OF THE EMBODIMENTS

Embodiments of the present invention will now be described with reference to the accompanying drawings which form a part hereof.

### First Embodiment

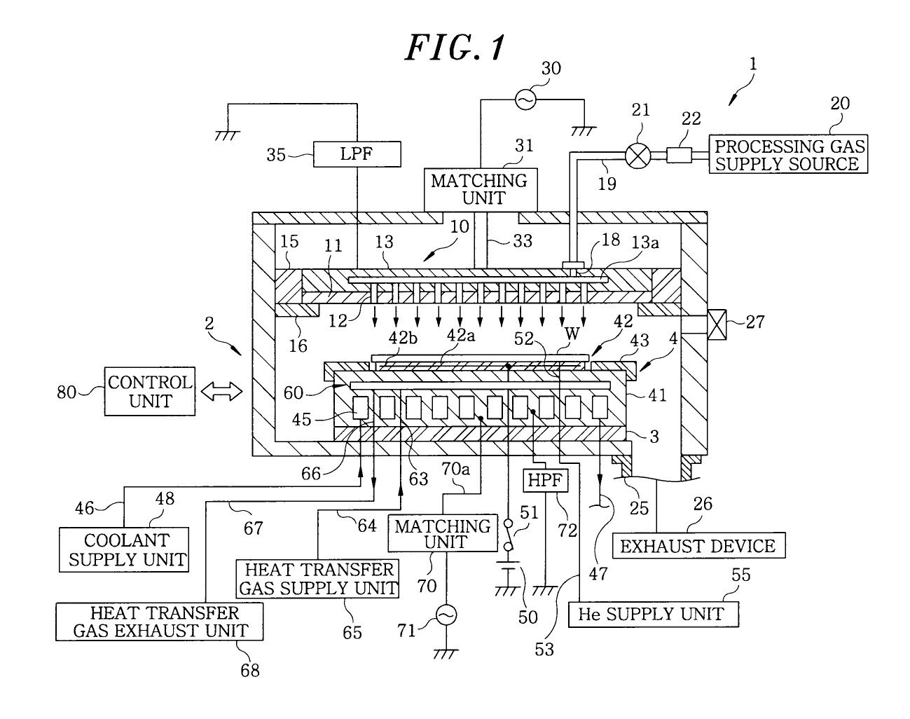

FIG. 1 is a cross sectional view showing a plasma processing apparatus 1 including a wafer mounting table (substrate mounting table) 4 in accordance with a first embodiment of the present invention.

The plasma processing apparatus 1 is a parallel plate type etching apparatus in which electrode plates are arranged in an upper and a lower portion to face each other in parallel and a capacitively coupled plasma is produced by a high frequency electric field generated between the electrodes.

The plasma processing apparatus 1 includes a cylindrical chamber 2, the surface of which is made of, e.g., an anodically oxidized aluminum. In a bottom portion of the plasma processing apparatus 1, the wafer mounting table (substrate mounting table) 4 in accordance with the first embodiment is provided via an insulating member 3 formed of, e.g., a ceramic or the like. A target substrate formed of, e.g., a semiconductor wafer W, is mounted on the wafer mounting table 4. The wafer mounting table 4 also serves as a lower electrode in the first embodiment as will be described later.

Above the wafer mounting table 4, a shower head 10 serving as an upper electrode is provided to face the wafer mounting table 4 in parallel. The shower head 10 includes an electrode plate 11 configured to face the wafer mounting table 4 and having a plurality of injection holes 12; and an electrode plate holder 13 of a water cooling structure configured to hold the electrode plate 11 formed of a conductive material, e.g., aluminum, the surface of which is anodically oxidized. A gas diffusion space 13a is provided inside the electrode plate holder 13.

A ring-shaped insulator 15 is provided between the shower head 10 and a sidewall of the chamber 2. The insulator 15 is joined to the sidewall of the chamber 2. Moreover, an insulating support member 16 is joined to a lower end portion of the insulator 15, the insulating support member 16 extending inwardly of the insulator 15 along its circumstance. The shower head 10 is spaced apart from the wafer mounting table 4 by, e.g., about 10 to 60 mm.

In the shower head 10, a gas inlet port 18 extends through the electrode plate holder 13 to the gas diffusion space 13a. One end of a gas supply line 19 is connected to the gas inlet port 18 and the other end thereof is connected to a processing gas supply source 20. A processing gas for etching is supplied from the processing gas supply source 20 to the shower head 10 through the gas supply line 19. Then, the processing gas is injected, via the gas diffusion space 13a, through the injection holes 12 to the wafer W. In the gas supply line 19, a valve 21 and a mass flow controller 22 are provided.

As the processing gas for the etching, various kinds of conventional processing gases can be employed. For example, it is possible to adequately use a halogen containing gas such as a fluorocarbon gas (CₓF_{y}) and a hydro fluorocarbon gas (CₚH_{q}Fᵣ). Further, a rare gas such as Ar, He or the like, N₂ gas, or O₂ gas may be added.

An exhaust pipe 25 is connected to a bottom portion of the chamber 2. The exhaust pipe 25 is also connected to an exhaust device 26. The exhaust device 26 includes a vacuum pump such as a turbo molecular pump or the like to exhaust the inside of the chamber 2 to be depressurized to a vacuum level, for example, a pressure of about 1 Pa or less. An automatic pressure control (APC) valve (not shown) is provided in the exhaust pipe 25, to thereby control the pressure inside the chamber 2 to a preset level. Moreover, a gate valve 27 is provided in the sidewall of the chamber 2. Accordingly, while the gate valve 27 is open, the wafer W is transferred between the chamber 2 and an adjacent load-lock chamber (not shown).

A first high frequency power supply 30 is connected to the shower head 10 via a matching unit 31 and a power supply rod 33. The power supply rod 33 is connected to an upper central portion of the electrode plate holder 13 of the shower head 10. A high frequency power is supplied to the shower head 10 through the power supply rod 33. Moreover, a low pass filter (LPF) 35 is connected to the shower head 10.

A high frequency electric field is generated between the upper electrode, i.e., the shower head 10 and the lower electrode, i.e., the wafer mounting table 4 by supplying a high frequency power from the high frequency power supply 30 to the shower head 10, to thereby produce a plasma of a processing gas. For example, a high frequency power of about 27 MHz or more (e.g., about 60 MHz) is supplied from the first high frequency power supply 30. As such, by supplying a high frequency power of a relatively high frequency, it is possible to generate a high density plasma in a desirable dissociation state. Accordingly, it is possible to perform the plasma processing under a low pressure condition.

The substantially cylindrical wafer mounting table 4 in accordance with the first embodiment includes a mounting table main body 41 provided on the insulating member 3. The mounting table main body 41 is made of a metal, e.g., aluminum. An electrostatic chuck 42 serving as a mounting unit on which the wafer W is mounted is placed on the mounting table main body 41. The electrostatic chuck 42 has a mounting surface on which the wafer W is mounted. The electrostatic chuck 42 has a diameter smaller than that of the mounting table main body 41.

A ring-shaped focus ring 43 is arranged on an upper peripheral portion of the mounting table main body 41 to surround the electrostatic chuck 42. The focus ring 43 is made of, e.g., an insulating material, to thereby improve the uniformity of etching. The mounting table main body 41 serves as the lower electrode.

A coolant circulation path 45 is provided inside the mounting table main body 41. The coolant circulation path 45 is connected to a coolant introduction line 46 and a coolant exhaust line 47. A coolant such as a fluorine-based nonreactive liquid is supplied from a coolant supply unit 48 to the coolant circulation path 45 via the coolant induction line 46 to be circulated, so that a cold heat of the circulated coolant is transferred to the wafer W. The temperature of the coolant is preferably lower but if the temperature of the coolant is too low, dew may be generated.

The electrostatic chuck 42 has a diameter slightly smaller than that of the wafer W. The electrostatic chuck 42 includes a main body 42a made of a dielectric material and an electrode 42b embedded in the main body 42a. A DC power supply 50 is connected to the electrode 42b. By supplying a DC power of, e.g., 1.5 kV, from the DC power supply 50 to the electrode 42b, the wafer W is attracted to and held on the electrostatic chuck 42 by an electrostatic force such as a Coulomb force or a Johnson-Rahbek force. The DC power supply 50 is turned off and on by a switch 51.

The dielectric material of the main body 42a may be a ceramic such as Al₂O₃, Zr₂O₃, Si₃N₄, or Y₂O₃.

A gas flow path 52 through which a heat transfer gas, e.g., He gas, is supplied is connected to a backside of the wafer W mounted on the wafer mounting table 4. A gas supply line 53 is connected to the gas flow path 52. The gas supply line 53 is also connected to a He supply unit 55. The He gas is supplied from the He supply unit 55 to the backside of the wafer W via the gas supply line 53 and the gas flow path 52 to transfer a cold heat of the coolant to the wafer W through the He gas. In other words, the He gas is supplied as a heat transfer gas for transferring a cold heat of the coolant.

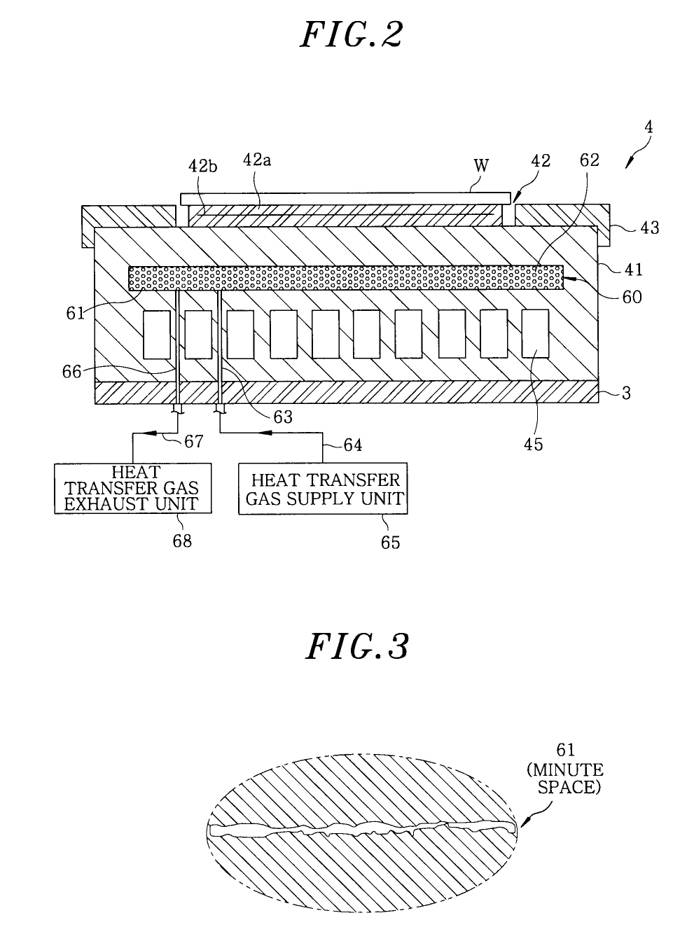

A heat transfer control part 60 is horizontally provided in the heat transfer path between the electrostatic chuck 42 and the coolant circulation path 45 inside the mounting table main body 41. The heat transfer control part 60, as shown in FIG. 2, includes a cavity portion 61 provided in the mounting table main body 41 and a solid member 62 filled in the cavity portion 61. The cavity portion 61 has a circular plate shape of a diameter greater than that of the wafer W and is located to correspond to the wafer W. The solid member 62 has a plurality of pores that communicate with one another.

It is preferable that the solid member 62 is made of a heat insulating material to insulate the heat when no heat transfer gas exists in the pores. It is also preferable that a material of the solid member 62 has relatively high hardness and mechanical strength to be stable and prevent the solid member 62 from being deformed readily. In view of this, the solid member 62 is preferably made of a porous ceramic. Alternatively, the solid member 62 may be made of a porous metal material, a foamed rubber, a glass fiber, or the like.

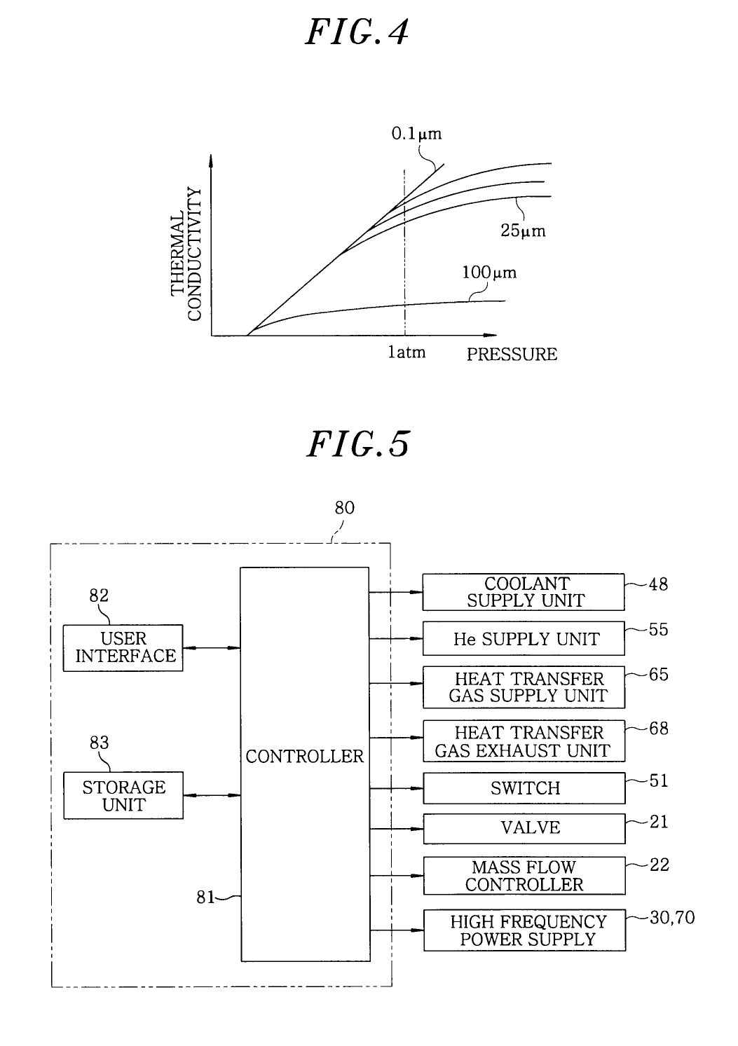

As the height of the cavity portion 61 becomes smaller, the cavity portion 61 has a higher controllability and, thus, it is preferable that the cavity portion 61 is a minute space having a height of 100 μm or less. As shown in FIG. 3, the cavity portion 61 as the minute space has a poor flatness microscopically but the height thereof can be obtained as an average height. FIG. 4 shows a relationship between thermal conductivity and pressure of gas depending on various heights of the minute space. As shown in FIG. 4, it can be seen that, in the minute spaces with the heights of 100 μm or less, change of the thermal conductivity to the pressure is relatively great and the controllability thereof is high.

Connected to the cavity portion 61 of the heat transfer control part 60 is a supply path 63 for supplying a heat transfer gas thereto. The supply path 63 is also connected to a heat transfer gas supply unit 65 via a supply line 64. Moreover, connected to the cavity portion 61 is an exhaust path 66 for exhausting the heat transfer gas therefrom. The exhaust path 66 is also connected to a heat transfer gas exhaust unit 68 via an exhaust line 67.

The heat transfer gas supply unit 65 has a function of supplying a heat transfer gas to the cavity portion 61 of the heat transfer control part 60 and, in the heat transfer control part 60, the heat transfer is performed through a heat transfer gas by filling the heat transfer gas in the pores of the solid member 62 at a preset pressure. At this time, the heat transfer can be controlled by adjusting the pressure of the heat transfer gas.

The heat transfer gas exhaust unit 68 has a function of exhausting the heat transfer gas from the cavity portion 61 of the heat transfer control part 60. The pores of the solid member 62 are exhausted to a vacuum level, thereby lowering the thermal conductivity of the heat transfer control part 60.

A second high frequency power supply 70 is connected, via a power supply line 70a, to the mounting table main body of the wafer mounting table 4 serving as the lower electrode and a matching unit 71 is provided in the power supply line 70a. A high frequency power supplied from the second high frequency power supply 70 has a frequency of, e.g., 100 kHz to 13.56 MHz (e.g., 2 MHz). By applying such a high frequency power, it is possible to apply an adequate ion action to the wafer W as the target object without damaging it. Meanwhile, a high pass filter (HPF) 72 is connected to the mounting table main body 41.

The plasma processing apparatus 1 includes a control unit 80. The control unit 80, as shown in FIG. 5, includes a controller 81, a user interface 82, and a storage unit 83. The controller 81, which is constituted by a microprocessor (computer), controls various components of the plasma processing apparatus 1, such as the coolant supply unit 48, the He supply unit 55, the heat transfer gas supply unit 65, the heat transfer gas exhaust unit 68, the exhaust device 26, the switch 51 of the DC power supply 50 for the electrostatic chuck 42, the valve 21, the mass flow controller 22, and other components.

The user interface 82 is connected to the controller 81. The user interface 82 includes a keyboard through which an operator inputs a command or the like to operate or manage the plasma processing apparatus 1, a display through which an operation status of the plasma processing apparatus 1 is visually displayed, and the like.

The storage unit 83 is also connected to the controller 81. The storage unit 83 stores control programs to control the components of the plasma processing apparatus 1; and processing recipes, i.e., programs for performing predetermined processes of the plasma processing apparatus 1. Specifically, the processing recipes are stored in a storage medium included in the storage unit 83. The storage medium may be a fixed unit such as a hard disk or a portable unit such as CDROM, DVD, or flash memory. Alternatively, the processing recipes may be adequately transmitted from another apparatus through, e.g., a dedicated line. As necessary, the controller 81 reads a pertinent processing recipe from the storage unit 83 by an instruction or the like inputted through the user interface 82 to execute the read processing recipe and thus a desired process is performed under the control of the controller 81 in the plasma processing apparatus 1.

Next, the processing operation of the plasma processing apparatus 1 will be described.

First, the wafer W as the target subject is loaded from a load lock chamber (not shown) into the chamber 2 after the gate valve 27 is opened. Then, the wafer W is mounted on the electrostatic chuck 42 of the wafer mounting table 4. Successively, the gate valve 27 is closed and the chamber 2 is exhausted to a preset vacuum level by the exhaust device 26.

Thereafter, the valve 21 is opened and a processing gas is supplied from the processing gas supply source 20 to the gas diffusion space 13a inside the shower head 10 via the gas supply line 19 and the gas inlet port 18, while the flow rate of the processing gas is being adjusted by the mass flow controller 22. Then, the processing gas is injected through the injection holes 12 uniformly over the wafer W as pointed by arrows illustrated in FIG. 1. As a result, the pressure inside the chamber 2 is maintained at a preset level.

Then, a high frequency power of 27 MHz or more (e.g., 60 MHz) is supplied from the first high frequency power supply 30 to the shower head 10 serving as the upper electrode, to thereby generate a high frequency electric field between the shower head 10 as the upper electrode and the wafer mounting table 4 as the lower electrode. The processing gas is decomposed to be converted to a plasma by the electric field and the wafer W is subjected to the plasma etching processing. By applying a DC voltage from the DC power supply 50 to the electrode 42b of the electrostatic chuck 42 while the plasma is generated as described above, the wafer W is attracted to and held on the electrostatic chuck 42.

In the meantime, a high frequency power of 100 kHz to 13.56 MHz (e.g., 2 MHz) is supplied from the second high frequency power supply 70 to the wafer mounting table 4 serving as the lower electrode. Accordingly, the ions in the plasma are attracted to the wafer mounting table 4, to thereby improve an etching anisotropy by ion assist.

After such a plasma etching is repeatedly performed on a predetermined number of wafers W, without loading, a plasma is generated in the chamber 2 without wafer to execute the waferless dry cleaning in the chamber 2.

In order to perform the plasma etching with high accuracy, it is required to control the temperature of the wafer W. Accordingly, a coolant is supplied to the coolant circulation path 45 and the He gas serving as a heat transfer gas is supplied to a backside of the wafer W. As a result, a cold heat of the coolant is transferred to the wafer W, to thereby control the temperature of the wafer W.

However, with only such temperature control, the temperature control range is narrow and it is not sufficient to a precise temperature control. Moreover, in the waferless dry cleaning, it is necessary that deposits be easily removed by increasing the temperature of the wafer mounting table 4 to be higher than during the process. However, in using the aforementioned method, it is difficult to increase the temperature of the wafer mounting table 4 to a desired level.

For that reason, in the first embodiment, the heat transfer control part 60 is provided inside the mounting table main body 41 of the wafer mounting table 4. The heat transfer control part 60, as described above, includes the cavity portion 61 and the solid member 62 filled in the cavity portion 61. The solid member 62, made of such as a porous ceramic or the like, has a plurality of pores that communicate with one another. The heat transfer is performed by supplying the heat transfer gas from the heat transfer gas supply unit 65 to the cavity portion 61 to fill the pores with the heat transfer gas. Moreover, by adjusting the pressure of the heat transfer gas, it is possible to control the heat transfer level.

Specifically, the thermal conductivity can be lowered by enabling the heat transfer gas exhaust unit 68 to exhaust the heat transfer gas from the pores of the solid member 62 to the vacuum level, while the cooling can be improved by supplying the heat transfer gas to the cavity portion 61 by the heat transfer gas supply unit 65 while exhausting the heat transfer gas from the cavity portion 61 by the heat transfer gas exhaust unit, to thereby circulate the heat transfer gas.

In this way, it is possible to perform the supply and exhaust of the heat transfer gas to and from the heat transfer control part 60 and the control of the pressure of the heat transfer gas. Accordingly, it is possible to improve the temperature controllability and responsivity of the wafer W.

In addition, the cavity portion 61 can have a wide pressure range from a high pressure level to a vacuum level. Accordingly, it is possible control the heat transfer level in a wide range. It is also possible to control the temperature of the wafer mounting table 4 and, further, the wafer W, in a wide temperature range. For example, when performing the waferless dry cleaning inside the chamber 2, removal of deposits can be facilitated by exhausting the pores of the solid member 62 to a vacuum level to suppress heat transfer and increasing the temperature the wafer mounting table 4.

In the case that the heat transfer control part 60 is a simple space, due to the difficulty in making flat the wafer mounting table 4 and the warpage caused by the difference in the pressure when it is kept vacuum, the wafer mounting table 4 may be brought into poor contact with the wafer W, thereby lowering the temperature controllability thereof. However, such a problem does not occur in this embodiment because the solid member 62 having the communicating pores is filled in the cavity portion 61. Moreover, since it is sufficient to fill only the pores of the solid member 62 with the heat transfer gas, the required amount of the heat transfer gas gets smaller than the case of filling the entire space with the heat transfer gas.

### Second Embodiment

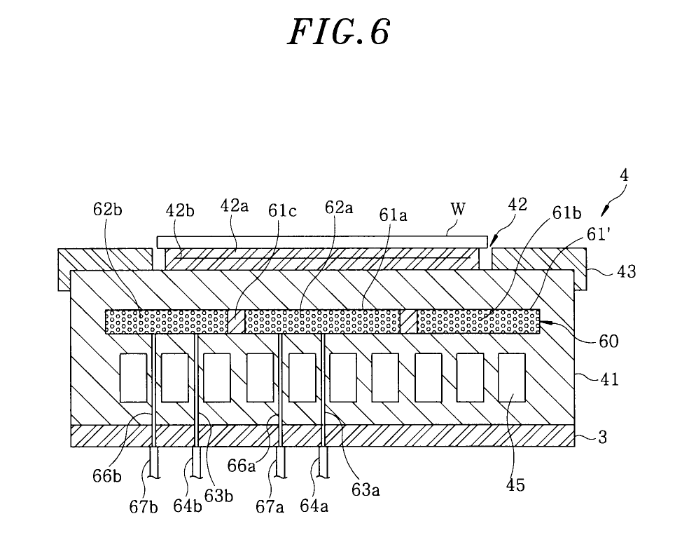

Next, a wafer mounting table (substrate mounting table) 4′ in accordance with a second embodiment of the present invention will be described. FIG. 6 is a cross sectional view showing the wafer mounting table 4′ in accordance with the second embodiment of the present invention. In the wafer mounting table 4′, a heat transfer control part 60′ is horizontally provided between the coolant circulation path 45 and the electrostatic chuck 42. The heat transfer control part 60′ includes a cavity portion 61′ provided therein to correspond to the wafer W, the cavity portion 61′ having a circular plate shape of a diameter greater than that of the wafer W. The cavity portion 61′ is concentrically divided into sub cavity portions, i.e., a central and an outer cavity portion 61a and 61b by a ring-shaped dividing member 61c. Solid members 62a and 62b are filled in the central and the outer cavity portion 61a and 61b, respectively. Like the solid member 62, each of the solid members 62a and 62b is made of, e.g., a porous ceramic and has a plurality of pores that communicate with one another.

Connected to the central cavity portion 61a, are a supply path 63a through which a heat transfer gas is supplied thereto and an exhaust path 66a through which the heat transfer gas is exhausted therefrom. The supply path 63a and the exhaust path 66a are connected to a heat transfer gas supply unit (not shown) and a heat transfer gas exhaust unit (not shown) via a supply line 64a and an exhaust line 67a, respectively.

Similarly, connected to the outer cavity portion 61b, are a supply path 63b through which a heat transfer gas is supplied thereto and an exhaust path 66b through which the heat transfer gas is exhausted therefrom. The supply path 63b and the exhaust path 66b are connected to the heat transfer gas supply unit and the heat transfer gas exhaust unit via a supply line 64b and an exhaust line 67b, respectively.

As such, in the heat transfer control part 60′, the cavity portion 61′ is divided into the central and the outer cavity portion 61a and 61b; and the heat transfer gases are individually supplied to and exhausted from the central and the outer cavity portion 61a and 61b, respectively. Accordingly, it is possible to independently perform the temperature control of the central and the outer cavity portion 61a and 61b by supplying the heat transfer gas in different pressure levels or different kinds of heat transfer gases to the central and outer cavity portion 61a and 61b, respectively, to transfer different heat to central and outer portions of the heat transfer control part 60′.

For example, when the temperature of a central portion of the wafer W is increased due to in-plane temperature nonuniformity of the wafer W, the temperature of the central portion of the wafer W can be decreased more than that of an outer portion thereof by supplying a heat transfer gas having a relatively higher pressure or higher thermal conductivity to the central cavity portion 61a and/or a heat transfer gas having a relatively lower pressure or lower thermal conductivity to the outer cavity portion 61b, to thereby make the heat transfer rate in the central portion of the heat transfer control part 60′ greater than that in the outer portion thereof.

In the inverse case, that is, when the temperature of the outer portion of the wafer W is increased, the temperature of the outer portion of the wafer W can be decreased more than that of the central portion thereof by supplying a heat transfer gas having a relatively higher pressure or higher thermal conductivity to the outer cavity portion 61b and/or a heat transfer gas having a relatively lower pressure or lower thermal conductivity to the central cavity portion 61a, to thereby make the heat transfer rate in the outer portion of the heat transfer control part 60′ greater than that in the central portion thereof. Accordingly, it is possible to improve the uniformity of the temperature of the wafer W.

Moreover, a desirable temperature distribution can be made by transferring different heat to the central portion and the outer portion of the heat transfer control part 60′. For example, deposits of the processing gas component may be easily attached to exposed portions of a side surface of the electrostatic chuck 42 and between the focus ring 43 and the electrostatic chuck 42 of the mounting table main body 41 due to the cooling by the coolant. The deposits may cause the etching conditions to be undesirably changed.

Accordingly, to prevent attachment of the deposits, a heat transfer gas having a relatively lower pressure (e.g., in a vacuum level) or lower thermal conductivity is supplied to the outer cavity portion 61b, thereby suppressing the heat transfer through the outer portion of the heat transfer control part 60′, thereby making it difficult to supply a cold heat. Therefore, the temperature of the exposed portion of the mounting table main body 41 or the like is increased which makes it difficult for deposits to be attached thereto.

Moreover, by changing the porosity or material of the solid member 62a or 62b, heat transfer rates in the central and the outer portion of the heat transfer control part 60′ can be made different, to thereby perform temperature control independently through the central and the outer portion.

It is preferable that the dividing member 61c by which the central cavity portion 61a is separated from the outer cavity portion 61b is made of a material having the substantially same thermal conductivity as the solid members 62a and 62b and also has no communicating pores. For example, if each of the solid members 62a and 62b is made of a porous ceramic, the dividing member 61c may be made of the same kind of a dense ceramic. Accordingly, the dividing member 61c can be prevented from becoming a heat spot. To heat the wafer W uniformly, it is preferable that the heat transfer gas remains in the central and the outer cavity portion 61a and 61b. However, to improve the cooling efficiency, it is preferable to allow the heat transfer gas to flow through the central and the outer cavity portion 61a and 61b.

In the second embodiment, the cavity portion 61′ is concentrically divided into two portions, i.e., the central and the outer cavity portion 61a and 61b. However, the number and shape of the divided portions are not limited thereto. The cavity portion 61′ may be divided into, e.g., three portions or in, e.g., a matrix shape.

### Third Embodiment

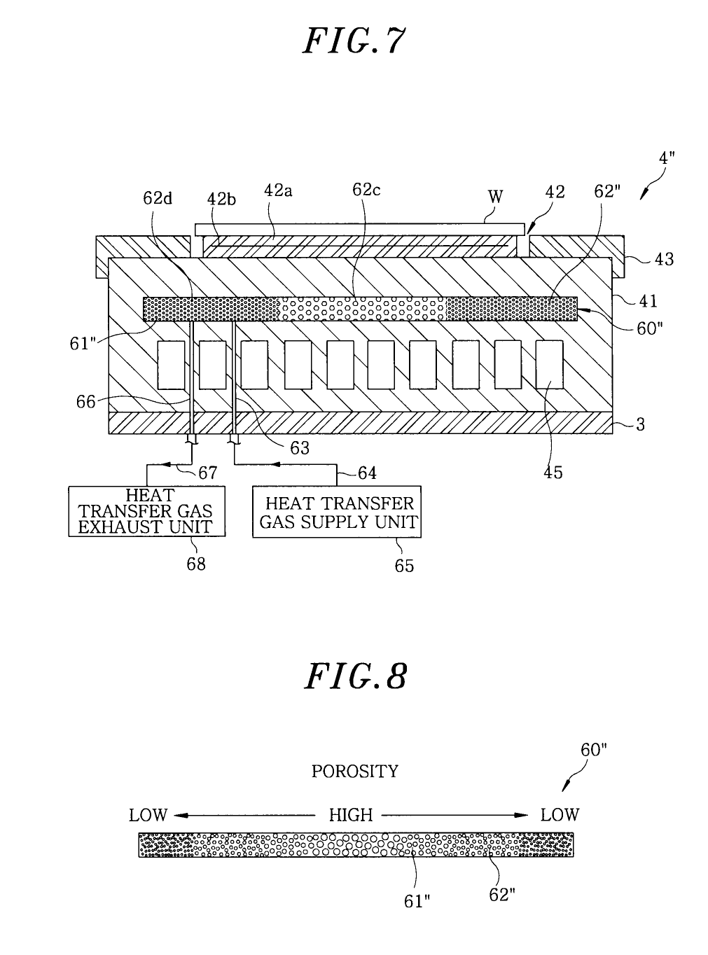

Next, a wafer mounting table (substrate mounting table) 4″ in accordance with a third embodiment of the present invention will be described. FIG. 7 is a cross sectional view showing the wafer mounting table 4″ in accordance with the third embodiment of the present invention. In the wafer mounting table 4″, a heat transfer control part 60″ is horizontally provided between the coolant circulation path 45 and the electrostatic chuck 42. The heat transfer control part 60″ includes a cavity portion 61″ provided in the mounting table main body 41 to correspond to the wafer W, the cavity portion 61″ having a circular plate shape of a diameter greater than that of the wafer W. A solid member 62″ as a single unit is filled in the cavity portion 61″. Like the solid member 62, the solid members 62″ is made of, e.g., a porous ceramic and has a plurality of pores that communicate with one another.

The solid member 62″ may have a nonuniform porosity distribution in an in-plane direction, i.e., a horizontal direction, of the wafer W. For example, as shown in FIG. 7, the solid member 62″ includes a central portion 62C and an outer portion 62d, which have different porosities. Alternatively, the solid member 62″ may include 3 portions having different porosities or may have a gradation in which the porosity becomes gradually lower from the central to the outer edge, for example.

As such, the solid member 62″ has the nonuniform porosity distribution in the horizontal direction. Accordingly, when the heat transfer gas is filled in the pores, the thermal conductivities can be differently distributed in the horizontal direction in spite of the heat transfer gas having the constant pressure. Therefore, when the in-plane temperature distribution of the wafer W is not uniform, the thermal conductivities can be differently distributed to improve the in-plane temperature uniformity of the wafer W. Further, it is possible to make a desirable temperature distribution.

### Fourth Embodiment

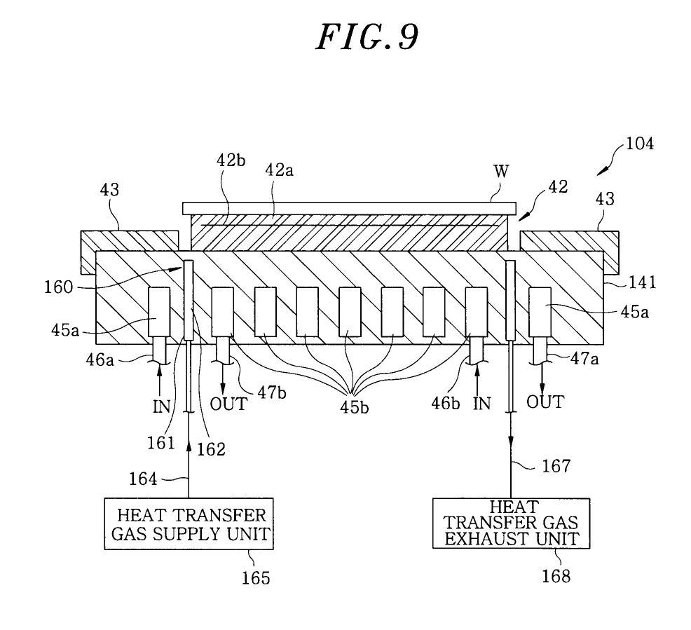

Next, a wafer mounting table (substrate mounting table) 104 in accordance with a fourth embodiment of the present invention will be described. FIG. 9 is a cross sectional view showing the wafer mounting table 104 in accordance with the fourth embodiment of the present invention. The wafer mounting table 104 includes a mounting table main body 141 having an outer and an inner coolant circulation path 45a and 45b.

A coolant introduction and a coolant exhaust line 46a and 47a and a coolant introduction and a coolant exhaust line 46b and 47b are connected to the outer and the inner coolant circulation path 45a and 45b, respectively, to enable coolants of different temperatures to flow therethrough. Accordingly, it is possible to make a predetermined temperature distribution on the wafer W.

A heat transfer control part 160 is provided between the outer and the inner coolant circulation path 45a and 45b. The heat transfer control part 160 includes a ring-shaped cavity portion 161 and a solid member 162 filled in the cavity portion 161 and having a plurality of pores that communicate with one another like the solid member 62. A supply line 164 is connected to the cavity portion 161 to supply a heat transfer gas thereto. The supply line 164 is also connected to a heat transfer gas supply unit 165. Further, an exhaust line 167 is connected to the cavity portion 161 to exhaust the heat transfer gas therefrom. The exhaust line 167 is also connected to a heat transfer gas exhaust unit 168.

By adjusting the pressure of the supplied heat transfer gas to control the thermal conductivity between the outer and the inner coolant circulation path 45a and 45b, it is possible to control an in-plane temperature gradient of the wafer W, to thereby control the temperature distribution on the wafer W with high accuracy.

The present invention is not limited to the above embodiments and various modifications may be made within the scope of the present invention. For example, although there is provided the electrostatic chuck serving as a mounting member on the mounting table main body in the present embodiments, the electrostatic chuck is not necessary. When no electrostatic chuck is employed, an upper surface of the mounting table main body serves as a mounting unit having a mounting surface.

Moreover, in the present embodiments, the coolant supply unit is employed as a heat source and, for example, the cold heat of a coolant is supplied to the mounting surface through the mounting table main body. Alternatively, a heating unit such as a heater may be employed as the heat source and a heat emitted from the heater is supplied through the mounting table main body.

Further, even though there is exemplified the parallel plate type plasma etching apparatus in which a high frequency power is applied to the upper electrode and the lower electrode, the present invention is not limited to the parallel plate type plasma etching apparatus. For example, another type of plasma etching apparatus such as an inductively coupled plasma etching apparatus may be employed. The present invention is also not limited to the etching; and ashing, CVD, or the like may be employed.

Moreover, instead of the plasma processing, other processings may be performed if the inside of the processing chamber is depressurized. Further, the target substrate is not limited to the semiconductor wafer. A flat panel display substrate or the like may be employed as the target substrate.

In accordance with the embodiments of the present invention, the heat transfer control part including the cavity portion is provided in the heat transfer path of the mounting table main body to correspond to a substrate mounted thereon and the solid member being filled in the cavity portion and has a plurality of pores that communicate with one another; and the heat transfer from the heat source is controlled by supplying or exhausting a heat transfer gas to or from the cavity portion.

Accordingly, unlike providing a space only, it is not difficult to make the mounting table flat and the mounting table is not warped when the space is kept vacuum. Further, it is possible to maintain the mounting table in sufficient contact with the substrate and control a temperature of the substrate with high accuracy to a desirable level with a good responsivity. Moreover, since the cavity portion may have a wide pressure range from a high pressure level (e.g., 1 atm) to a vacuum level, it is possible to control a heat transfer and the temperature of the substrate in a wide range.

By dividing the cavity portion into a plurality of sub cavity portions in an in-plane direction of the substrate and enabling the supplying and exhausting of heat transfer gases to and from the sub cavity portions to individually be performed by the heat transfer gas supply and the heat transfer gas exhaust unit, respectively, it is possible to individually control heat transfer levels of the respective sub cavity portions and make an uniform temperature distribution on the substrate. Further, a desirable temperature distribution can be made by controlling the heat transfer level of the cavity portion, to thereby prevent deposits from being attached to a local portion.

By making the porosity distribution nonuniform in the in-plane direction of the substrate in the solid member, the heat transfer distribution can be made according to the porosity distribution, to thereby make uniform the temperature of the substrate or obtain the desirable temperature distribution of the substrate.

In addition, when making a temperature distribution of the substrate nonuniform, it is possible to control a temperature gradient between a plurality of different-temperature heat sources for transferring cold heats or heats to the upper portion of the mounting table main body by providing the heat transfer control part between the different-temperature heat sources.

While the invention has been shown and described with respect to the embodiments, it will be understood by those skilled in the art that various changes and modification may be made without departing from the scope of the invention as defined in the following claims.

What is claimed is:

1. A substrate mounting table for mounting a substrate thereon in a substrate processing apparatus, the substrate mounting table comprising:
a mounting table main body;
a mounting unit provided at an upper portion of the mounting table main body and having a mounting surface on which the substrate is mounted;
a heat source configured to transfer a cold heat or a heat to the upper portion of the mounting table main body;
a heat transfer control part including a cavity portion provided in a heat transfer path of the mounting table main body to correspond to the mounted substrate and a solid member filled in the cavity portion and having pores that communicate with one another, the heat transfer control part controlling a heat transfer level from the heat source by supplying or exhausting a heat transfer gas to or from the cavity portion;
a heat transfer gas supply unit for supplying the heat transfer gas to the cavity portion;
a heat transfer gas exhaust unit for exhausting the heat transfer gas from the cavity portion; and
a controller for controlling the supplying and the exhausting of the heat transfer gas to and from the cavity portion by the heat transfer gas supply unit and the heat transfer gas exhaust unit, respectively.

2. The substrate mounting table of claim 1, wherein the heat source includes a coolant path provided in the mounting table main body and a coolant flows through the coolant path.

3. The substrate mounting table of claim 1, wherein the solid member is made of a heat insulating material.

4. The substrate mounting table of claim 3, wherein the solid member is made of a porous ceramic.

5. The substrate mounting table of claim 1, wherein the cavity portion is divided into a plurality of sub cavity portions in an in-plane direction of the substrate, and the supplying and exhausting of heat transfer gases to and from the sub cavity portions are individually performed by the heat transfer gas supply unit and the heat transfer gas exhaust unit, respectively.

6. The substrate mounting table of claim 5, wherein the cavity portion is concentrically divided into the sub cavity portions.

7. The substrate mounting table of claim 5, wherein a dividing member made of a dense material of the same kind as the solid member is provided between the adjacent sub cavity portions.

8. The substrate mounting table of claim 5, wherein the controller individually controls the pressures of the heat transfer gases supplied to the respective sub cavity portions.

9. The substrate mounting table of claim 5, wherein the controller controls different kinds of heat transfer gases to be supplied to the respective sub cavity portions.

10. The substrate mounting table of claim 5, wherein solid members having different porosities or materials are filled in the respective sub cavity portions.

11. The substrate mounting table of claim 1, wherein the solid member filled in the cavity portion has a nonuniform porosity distribution in an in-plane direction of the substrate.

12. The substrate mounting table of claim 11, wherein the solid member filled in the cavity portion has a plurality of regions having different porosities in the in-plane direction of the substrate.

13. The substrate mounting table of claim 11, wherein the solid member filled in the cavity portion has a gradation of the porosities in the in-plane direction of the substrate.

14. The substrate mounting table of claim 1, wherein the cavity portion is a minute space having a height of about 100 μm or less.

15. The substrate mounting table of claim 1, wherein the mounting unit includes an electrostatic chuck for electrostatically attracting the substrate.

16. The substrate mounting table of claim 1, further comprising another heat transfer gas supply unit for supplying another heat transfer gas to a backside of the substrate mounted on the mounting unit.

17. A substrate mounting table for mounting a substrate thereon in a substrate processing apparatus, the substrate mounting table comprising:
a mounting table main body;
a mounting unit provided at an upper portion of the mounting table main body and having a mounting surface on which the substrate is mounted;
a plurality of different-temperature heat sources configured to transfer cold heats or heats to the upper portion of the mounting table main body;
a heat transfer control part including a cavity portion provided between the heat sources of the mounting table main body and a solid member filled in the cavity portion and having pores that communicate with one another, the heat transfer control part controlling a heat transfer level between the heat sources by supplying or exhausting a heat transfer gas to or from the cavity portion;
a heat transfer gas supply unit for supplying the heat transfer gas to the cavity portion;
a heat transfer gas exhaust unit for exhausting the heat transfer gas from the cavity portion; and
a controller for controlling the supplying and the exhausting of the heat transfer gas to and from the cavity portion by the heat transfer gas supply unit and the heat transfer gas exhaust unit, respectively.

18. A substrate processing apparatus comprising:
a processing chamber configured to accommodate a substrate therein, the inside of the processing chamber being depressurized;
a substrate mounting table of claim 1 provided in the processing chamber, the substrate being mounted on the substrate mounting table; and
a processing unit for performing a predetermined processing on the substrate in the processing chamber.

19. The apparatus of claim 18, wherein the processing unit includes a plasma generation unit and the substrate is subjected to a plasma processing by using a plasma generated by the plasma generation unit.
